(19) United States
(12) Patent Application Publication
(10) Pub. No.: US 2026/0114021 A1
(43) Pub. Date: Apr. 23, 2026

(54) SEMICONDUCTOR CIRCUIT AND SEMICONDUCTOR MODULE

(71) Applicant: FUJI ELECTRIC CO., LTD., Kanagawa (JP)

(72) Inventors: Kohei YAMAUCHI, Hachioji-City (JP); Eiji MOCHIZUKI, Matsumoto-city (JP)

(21) Appl. No.: 19/339,175

(22) Filed: Sep. 24, 2025

(30) Foreign Application Priority Data
Oct. 17, 2024 (JP) 2024-181515

(51) Int. Cl. H10D 80/20; H01L 23/00; H01L 23/31; H01L 23/367; H01L 23/498; H01L 25/07

(52) U.S. Cl. CPC H10D 80/251; H10W 40/22; H10W 70/658; H10W 74/141; H10W 90/00; H10W 74/142; H10W 74/15; H10W 90/724; H10W 90/734

(57) ABSTRACT

A semiconductor circuit, including a plurality of first devices and a plurality of second devices provided on the front surface of the main board, wherein each of the first device and the second device has a plurality of electrodes including a first main electrode and a second main electrode arranged on an upper surface, and the first main electrode and the second main electrode are connected to the front surface of the main board; each of the first devices has a first end side facing the second device; each of the second devices has a second end side facing the first device; a whole region between the first main electrode and the first end side in the first direction is a first region; and a whole region between the second main electrode and the second end side in the first direction is a second region.

The contents of the following patent application(s) are incorporated herein by reference:

NO. 2024-181515 filed in JP on Oct. 17, 2024.

### BACKGROUND

### 1. Technical Field

The present invention relates to a semiconductor circuit and a semiconductor module.

### 2. Related Art

In Patent document 1, a semiconductor module is disclosed to “comprise a insulating circuit board 1, and semiconductor chips 3a to 3d mounted on the insulating circuit board 1 via bonding materials 2a to 2d such as solder or sinter materials” (paragraph 0015). In Patent document 2, a power semiconductor circuit is disclosed to be “characterized in being a power semiconductor circuit that connects the two surface-mount type power semiconductor devices as at least an upper arm and a lower arm in series, wherein an orientation of a drain and a source of the power semiconductor device on an upper arm side is inverted with an orientation of a drain and a source of the power semiconductor device on a lower arm element side, and a power semiconductor device on the upper arm side and a power semiconductor device on the lower arm side are connected in adjacent on different circuit substrates” (paragraph 0015). In FIG. 4 of the Patent document 2, arrangement of a drain electrode 6, a source electrode 7 and a gate electrode 8 is disclosed, and in paragraph 0003, it is described that “in the example described below, the gate electrode 8 is not an essential element, thereby omitted in the illustration”.
Patent Document 1: Japanese Patent Application Publication No. 2022-191879
Patent Document 2: Japanese Patent Application Publication No. 2017-005212

### BRIEF DESCRIPTION OF THE DRAWINGS

FIG. 1 illustrates a perspective view of a semiconductor chip 10 according to the present embodiment.

FIG. 2 illustrates a perspective view of a device 200 according to the present embodiment.

FIG. 3 illustrates a perspective view of a mounting substrate 210 according to the present embodiment.

FIG. 4 illustrates a perspective view according to the present embodiment, where a semiconductor chip 10, a source electrode 220, a gate electrode 240 and a sub-source electrode 250 are in a bonded state on the mounting substrate 210.

FIG. 5 illustrates an arrangement of wiring of a semiconductor circuit 800 according to the present embodiment.

FIG. 6 illustrates an enlarged drawing of a first device 200-1 and a second device 200-2 arranged facing each other in a first direction.

FIG. 7 illustrates an example of A-A′ cross section in FIG. 5.

FIG. 8 illustrates an arrangement of wiring of a semiconductor circuit 900 in a comparative example.

FIG. 9 illustrates an example of a B-B′ cross section in FIG. 8.

FIG. 10A illustrates an example of an enlarged drawing in a top view of an interference region 30.

FIG. 10B illustrates another example of an enlarged drawing in a top view of the interference region 30.

FIG. 11 illustrates a variant of the semiconductor circuit 800.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, a case where a term such as “same” or “equal” is mentioned may include a case where an error due to a variation in manufacturing or the like is included. The error is, for example, within 10%.

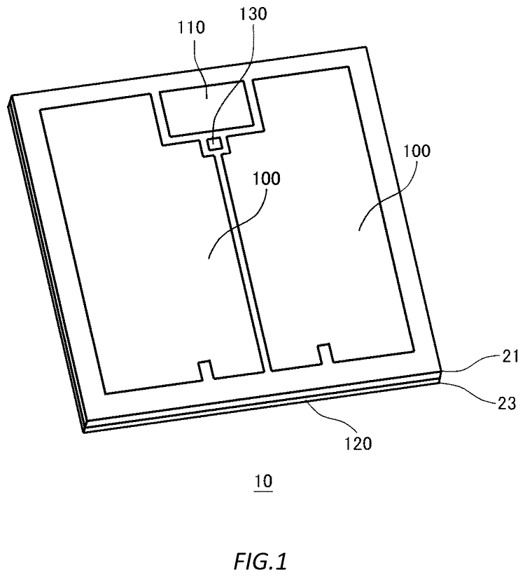

FIG. 1 illustrates a perspective view of a semiconductor chip 10 according to the present embodiment. The semiconductor chip 10 is a switching element such as a MOSFET (Metal-Oxide Semiconductor Field-Effect Transistor). The semiconductor chip 10 may be a vertical-type switching element. The semiconductor chip 10 in the present example is a vertical-type MOSFET. The semiconductor chip 10 may be a Si semiconductor device such as a Si-MOSFET, or may be a SiC semiconductor device such as a SiC-MOSFET that can switch faster, or may be a device using a wide gap semiconductor such as GaN, diamond, gallium nitride materials, gallium oxide materials, AlN, AlGaN or ZnO. Alternatively, the semiconductor chip 10 may be a semiconductor switch element such as an IGBT (insulated gate bipolar transistor), or may be a SiC-IGBT. Also, the semiconductor chip 10 may be a HEMT (High-Electron-Mobility Transistor).

The semiconductor chip 10 has an upper surface 21 and a lower surface 23. The upper surface 21 and the lower surface 23 are two main surfaces of the semiconductor chip 10. The semiconductor chip 10 has a source pad 100 and a gate pad 110 arranged on the upper surface 21, and a drain pad 120 arranged on the lower surface 23. The source pad 100 is an example of the first main pad, and the drain pad 120 is an example of the second main pad. For example, when the semiconductor chip 10 is IGBT, an emitter pad is provided instead of a source pad 100 as a first main pad, and a collector pad is provided instead of a drain pad 120 as a second main pad. Each pad may be formed of a metal such as aluminum. By applying a predetermined gate voltage on the gate pad 110, a main current flows between the source pad 100 and the drain pad 120. The semiconductor chip 10 may further has a sense pad 130 on the upper surface 21.

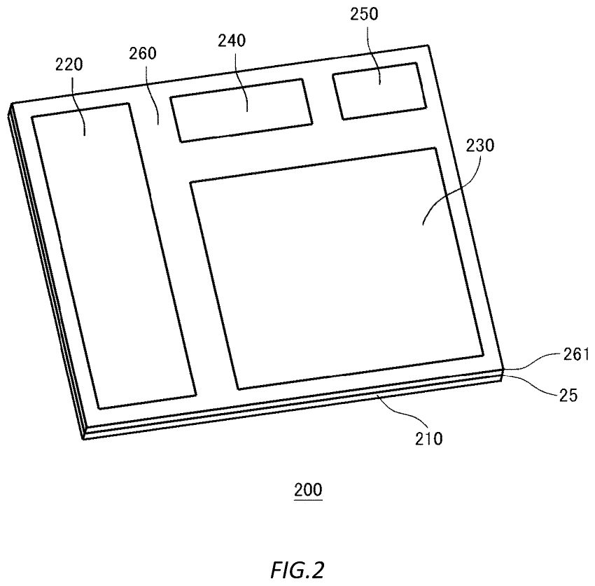

FIG. 2 illustrates a perspective view of the device 200 according to the present embodiment. In general, the semiconductor module using the switching element as the semiconductor chip 10 shown in FIG. 1 employs a structure that bonds a pad (drain pad 120) provided on one surface (for example, the lower surface 23) of the switching element to a wiring pattern on the substrate, and electrically connects each pad (for example, the source pad 100, the gate pad 110 and the sense pad 130) of the other surface (for example, the upper surface 21) to another wiring pattern by a wire bonding. Such a semiconductor module is implemented as an integral module by encapsulating, using a resin, a substrate on which the switching element is mounted, each bonding wire, and each metal plate connected to a positive terminal, a negative terminal and an output terminal.

On the other hand, the device 200 has a structure that exposes each electrode electrically connected to each pad of the semiconductor chip 10 on one surface of the board-shaped device 200. In the present embodiment, the device 200 comprises a mounting substrate 210, a source electrode 220, a drain electrode 230, a gate electrode 240, a sub-source electrode 250 and a sealing portion 260.

The mounting substrate 210 mounts the semiconductor chip 10 on a mounting surface 25 (the upper surface in the drawing). The source electrode 220 is electrically connected to the source pad 100 of the semiconductor chip 10. The drain electrode 230 is electrically connected to the drain pad 120 of the semiconductor chip 10. The gate electrode 240 is electrically connected to the gate pad 110 of the semiconductor chip 10. The sub-source electrode 250 is electrically connected to the source pad 100 of the semiconductor chip 10.

The source electrode 220 is an example of a first main electrode, and the drain electrode 230 is an example of a second main electrode. The first main electrode and the second main electrode are electrodes through which a main current of the semiconductor chip 10 flows. The main current refers to a current with a largest amplitude among the currents flowing through the semiconductor chip 10. The main current is, for example, a current flowing between an emitter and a collector in an IGBT, or a current flowing between a source and a drain in a MOSFET. For example, when the semiconductor chip 10 is an IGBT, an emitter electrode is provided instead of the source electrode 220 as the first main electrode, and a collector electrode is provided instead of the drain electrode 230 as the second main electrode. Also, the sub-source electrode 250 is an example of a sub-electrode. When the semiconductor chip 10 is an IGBT, a sub-emitter electrode is provided instead of the sub-source electrode 250 as the sub-electrode.

One of the two main surfaces of the device 200 is defined as the upper surface 261. The upper surface 261 is a surface opposite to a side of the mounting substrate 210 in the device 200. The upper surface 261 is also a surface of the sealing portion 260. The source electrode 220, the drain electrode 230, the gate electrode 240 and the sub-source electrode 250 are arranged on the upper surface 261. The sealing portion 260 exposes at least a part of the source electrode 220, the drain electrode 230, the gate electrode 240 or the sub-source electrode 250 while covering the semiconductor chip 10 and the mounting surface 25. The same is true between the sub-source electrode 250 and the other electrodes. The sealing portion 260 may be a molding material. However, the sealing portion 260 may not be provided.

Instead of modularizing the switching element such that the semiconductor chip 10 as previously described, by bonding each electrode on the upper surface 261 of the device 200 to the wiring pattern on the substrate by using the device 200 in the present embodiment, all necessary electrodes on the semiconductor chip 10 can be electrically connected to wiring on the substrate without wire bonding. Therefore, as described below, it can be directly bonded to a printed circuit board or the like, making it possible to reduce the thickness of the module and greatly reduce the inductance and thermal resistance.

Note that the device 200 may further have an electrode on the upper surface 261, which is electrically connected to the sense pad 130. Also, any of the source electrode 220 or the sub-source electrode 250 is electrically connected to the source pad 100 of the semiconductor chip 10, but the source electrode 220 is used for a large surface area and a large current (main current) flowing therethrough, and the sub-source electrode 250 is used for controlling the semiconductor chip 10 in a pair with the gate electrode 240. In another form, the device 200 may not include a sub-source electrode 250, and in this case, the source electrode 220 may be used for controlling the semiconductor chip 10.

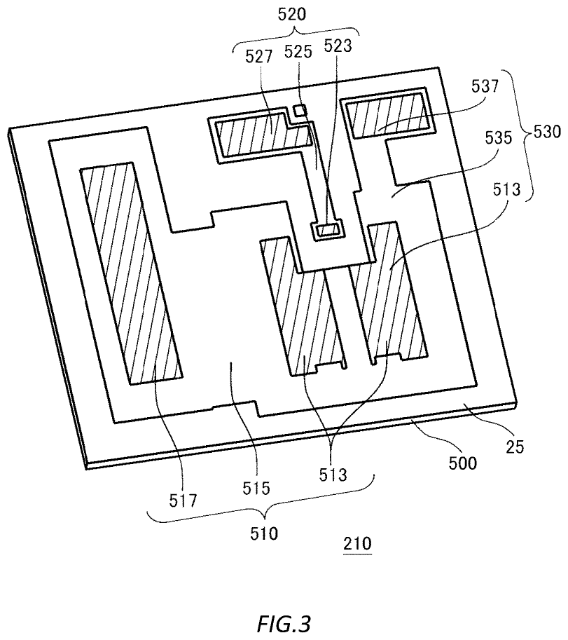

FIG. 3 illustrates a perspective view of the mounting substrate 210 according to the present embodiment. The mounting substrate 210 has an insulating substrate 500, a source electrode wiring 510, a gate electrode wiring 520, and a sub-source electrode wiring 530.

The insulating substrate 500 may be a substrate made of Si, silicon nitride, or aluminum nitride, or the like, or may be made of other ceramic materials, or the like. A wiring pattern of the source electrode wiring 510, the gate electrode wiring 520 and the sub-source electrode wiring 530 is provided on the mounting surface 25 that is the surface of the insulating substrate 500.

The source electrode wiring 510 is formed of a conductive metal film or metal board such as copper. The source electrode wiring 510 includes a source pad contact 513, a wiring 515, and a source electrode contact 517. The source pad contact 513 is an area connected to the source pad 100 of the semiconductor chip 10. The wiring 515 electrically connects the source pad contact 513 and the source electrode contact 517 in between. The source electrode contact 517 is an area connected to the source electrode 220. In FIG. 3, the source pad contact 513 and the source electrode contact 517 are hatched. The source electrode wiring 510 is an example of the first main electrode wiring. For example, when the semiconductor chip 10 is an IGBT, the first main electrode wiring becomes an emitter electrode wiring instead of the source electrode wiring 510.

The gate electrode wiring 520 is formed of a conductive metal film or a metal board such as copper, similar to the source electrode wiring 510. The gate electrode wiring 520 includes a gate pad contact 523, a wiring 525 and a gate electrode contact 527. The gate pad contact 523 is an area connected to the gate pad 110 of the semiconductor chip 10. The wiring 525 electrically connects the gate pad contact 523 and the gate electrode contact 527 in between. The gate electrode contact 527 is an area connected to the gate electrode 240. In FIG. 3, the gate pad contact 523 and the gate electrode contact 527 are hatched.

The sub-source electrode wiring 530 is formed of a conductive metal film or a metal board such as copper, similar to the source electrode wiring 510. The sub-source electrode wiring 530 includes a source pad contact 513, a wiring 535 and a sub-source electrode contact 537. The source pad contact 513 is shared with the source electrode wiring 510. The sub-source electrode wiring 530 may utilize a part of the source pad contact 513 used by the source electrode wiring 510. The wiring 535 electrically connects the source pad contact 513 and the sub-source electrode contact 537 in between. A wiring width of the wiring 535 may be smaller than that of the wiring 515. The sub-source electrode contact 537 is an area connected to the sub-source electrode 250. In FIG. 3, the sub-source electrode contact 537 is hatched. The sub-source electrode wiring 530 is an example of the sub-electrode wiring. For example, when the semiconductor chip 10 is an IGBT, the sub-electrode wiring becomes a sub-emitter electrode wiring instead of the sub-source electrode wiring 530.

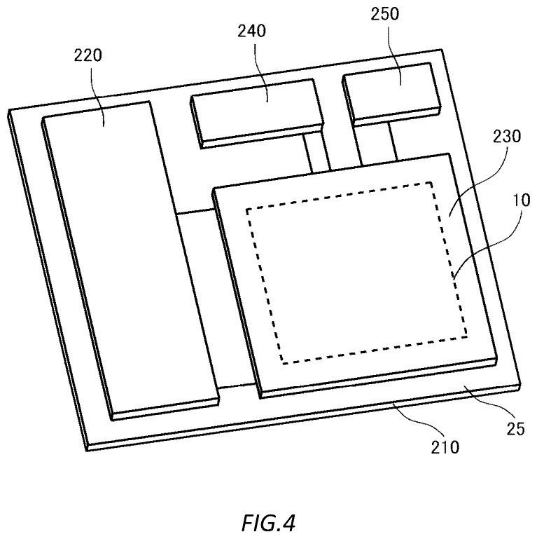

FIG. 4 illustrates a perspective view of the mounting subtract 210 according to the present embodiment, where a semiconductor chip 10, a source electrode 220, a gate electrode 240 and a sub-source electrode 250 are in a bonded state on the mounting substrate 210. The drain electrode 230 is bonded to the drain pad 120 of the semiconductor chip 10 in the present example. The drain electrode 230 is also a conductive plate-like member such as a copper plate. In FIG. 4, the position of the semiconductor chip 10 located below the drain electrode 230 is indicated by a dotted line.

The drain electrode 230 may be bonded to the drain pad 120 by using a nanosilver sintering agent or by a direct gold-to-gold bond. In addition to the above, the drain electrode 230 may be bonded by solder materials or by direct copper-copper bonding. Also, a plurality of bumps arranged regularly or irregularly on the drain electrode 230 may be bonded to the drain pad 120 of the semiconductor chip 10. Thereby, the drain electrode 230 is electrically connected to the drain pad 120. Note that the drain electrode 230 may not be provided. In this case, the drain pad 120 may be directly exposed on the upper surface 261 of the device 200. The drain electrode 230 in the present specification includes a drain pad 120 in this case.

The semiconductor chip 10 is bonded to the mounting surface 25 of the mounting substrate 210 with the upper surface 21 of the semiconductor chip 10 in FIG. 1 facing downward. Thereby, the source pad 100 of the semiconductor chip 10 is bonded to the source electrode wiring 510 and the source pad contact 513 of the sub-source electrode wiring 530, and the gate pad 110 of the semiconductor chip 10 is bonded to the gate pad contact 523 of the gate electrode wiring 520. These bonding methods may be similar to the bonding methods of the drain electrode 230 to the drain pad 120.

In FIG. 4, the source electrode 220, the gate electrode 240, and the sub-source electrode 250 are bonded to the mounting substrate 210 according to the present embodiment. The source electrode 220 is bonded to the source electrode contact 517 of the source electrode wiring 510. The gate electrode 240 is bonded to the gate electrode contact 527 of the gate electrode wiring 520. The sub-source electrode 250 is bonded to the sub-source electrode contact 537 of the sub-source electrode wiring 530. These bonding methods may be similar to the bonding methods of the drain electrode 230 to the drain pad 120.

Thereby, the source electrode 220 is electrically connected to the source pad 100, and the gate electrode 240 is electrically connected to the gate pad 110. A main current flows between the drain electrode 230 and the source electrode 220, and a control signal of the semiconductor chip 10 is input into the gate electrode 240.

As shown in FIG. 4, the source electrode 220 is arranged at a position not overlapping the semiconductor chip 10. The same is true for the gate electrode 240 and the sub-source electrode 250. This can ensure a certain distance between the semiconductor chip 10 and each electrode, and can suppress the effect of heat generation from the semiconductor chip 10.

When a gate voltage is applied to the gate electrode 240 with the potential of the source electrode 220 as a reference potential, the gate voltage may be affected by noise due to the main current flowing through the source electrode 220. Also, the heat of the source electrode 220 may distort the time waveform of the gate signal. Therefore, as described above, the control signal (gate voltage) of the semiconductor chip 10 may be applied to the gate electrode 240 with the potential of the sub-source electrode 250 as the reference potential.

The sub-source electrode 250 has the same potential as the source electrode 220, and a current corresponding to the current (main current) flowing between the drain electrode 230 and the source electrode 220 flows through the sub-source electrode 250. For example, a detection current, which is smaller than the main current and has a predetermined ratio to the main current, flows through the sub-source electrode 250. The semiconductor chip 10 may be provided with a main region through which the main current flows, and a detection region through which the detection current flows. The ratio of the detection current to the main current is determined according to the ratio of the detection region to the main region. The magnitude of the main current can be detected by measuring the detection current. Since the sub-source electrode 250 in the present example is arranged at a position not overlapping the semiconductor chip 10, heat generation from the semiconductor chip 10 is less likely to be transmitted, and distortion of the gate signal can be suppressed. Also, since the gate electrode 240 in the present example is arranged at a position not overlapping the semiconductor chip 10, heat generation from the semiconductor chip 10 is less likely to be transmitted, and distortion of the gate signal can be suppressed.

Note that when the sub-source electrode 250 is not provided, the gate voltage may be applied between the gate electrode 240 and the source electrode 220. Also in this case, since the source electrode 220 is arranged at a position not overlapping the semiconductor chip 10, heat generation from the semiconductor chip 10 is less likely to be transmitted, and distortion of the gate signal can be suppressed.

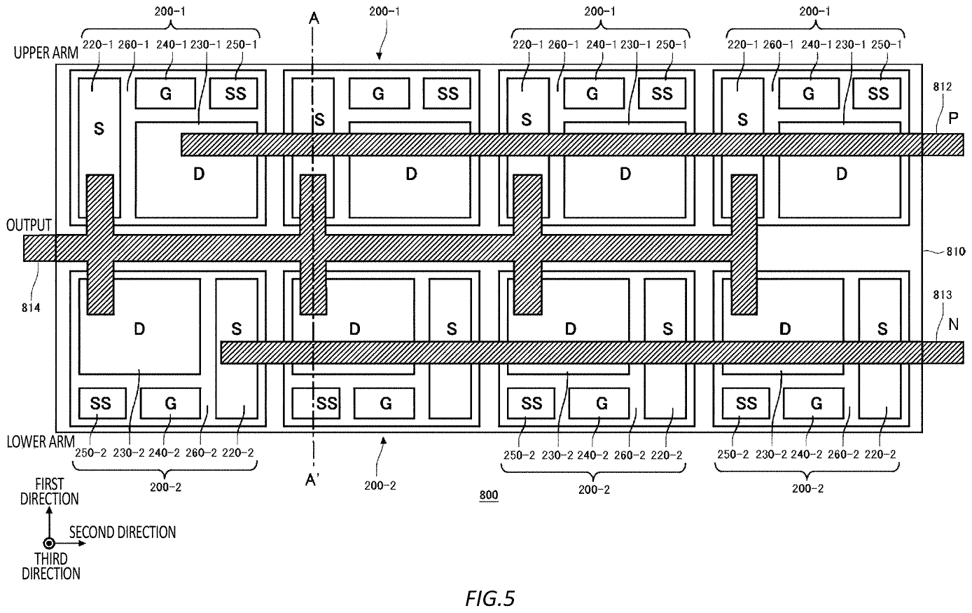

FIG. 5 illustrates an arrangement of the wiring of the semiconductor circuit 800 according to the present embodiment. The semiconductor circuit 800 in the present example includes a plurality of devices 200 and a main board 810. Although the semiconductor circuit 800 may include a cooler on a surface on a side opposite to the main board 810 of the device 200, in FIG. 5, the cooler is omitted.

The semiconductor circuit 800 according to the present embodiment is an inverter device, and includes a plurality of devices 200. The plurality of devices 200 are respectively assigned to an upper arm and a lower arm of each of one or more phases. In the example of FIG. 5, the semiconductor circuit 800 is provided with a half-bridge circuit, with four semiconductor devices 200 assigned to each upper arm and four semiconductor devices 200 assigned to each lower arm. Note that the semiconductor circuit 800 may include any number of the semiconductor devices 200 according to applications, or may include another circuit such as a three-phase inverter.

The main board 810 may be a printed circuit board. The main board 810 may have a positive wiring 812, a negative wiring 813 and an inter-device wiring 814 on the inner layer. In the case of the present example, a DC voltage is applied between the positive wiring 812 and the negative wiring 813 from an external power supply, and an AC voltage is output from the inter-device wiring 814. As described below, the positive wiring 812, the negative wiring 813 and the inter-device wiring 814 may be conductive patterns formed in the same inner layer of the main board 810. The positive wiring 812, the negative wiring 813 and the inter-device wiring 814 are connected to the device 200 by vias or the like, which will be described below.

In the semiconductor circuit 800, the plurality of devices 200 are arranged side by side in a predetermined direction. The plurality of devices 200 in the present example are arranged side by side in a first direction. The first direction is a direction parallel to the front surface of the main board 810. The front surface is a surface of two main surfaces of the main board 810, to which the device 200 is bonded. Among the devices 200 arranged side by side in the first direction, one is defined as a first device 200-1, and the other is defined as a second device 200-2. In the present example, the first device 200-1 constitutes the upper arm, and the second device 200-2 constitutes the lower arm. In FIG. 5 and subsequent drawings, the first device 200-1 and its configuration may be labeled with a sign of −1, and the second device 200-2 and its configuration may be labeled with a sign of −2.

The plurality of first devices 200-1 may be arranged side by side in a second direction. The second direction is parallel to the front surface of the main board 810, and is a direction intersected by the first direction. Similarly, the plurality of second devices 200-2 may be arranged side by side in the second direction. In the present example, the second direction is orthogonal to the first direction, the first device 200-1 and the second device 200-2 are arranged side by side in a row of four in the second direction. Note that the second direction in which the plurality of first devices 200-1 are arranged and the second direction in which the plurality of second devices 200-2 are arranged may have an error of ±5° or less. Each first device 200-1 may face the second device 200-2 in the first direction. Also, a direction perpendicular to the front surface of the main board 810 is defined as a third direction. The third direction is a direction perpendicular to the first direction and the second direction.

As described above, the source electrode 220 is an example of the first main electrode, and the drain electrode 230 is an example of the second main electrode. That is, each first device 200-1 has a first main electrode (source electrode 220-1) and a second main electrode (drain electrode 230-1), each second device 200-2 has a first main electrode (source electrode 220-2) and a second main electrode (drain electrode 230-2). That is, the first main electrode of the first device 200-1 and the first main electrode of the second device 200-2 refer to electrodes of the same type, but the individual ones refer to different electrodes. The type of electrode may refer to the type of terminal of the device 200 (for example, emitter, collector, source, drain, gate, base, anode, cathode, or the like). The same is true for the second main electrode. In the description below, the first device 200-1 and the second device 200-2 are MOSFETs, as an example.

On the upper surface 261 of the first device 200-1 in the present example, the source electrode 220-1 and the drain electrode 230-1 are arranged side by side in the second direction. In other words, the first main electrode of the first device 200-1 and the second main electrode of the first device 200-1 are arranged side by side in the second direction. Similarly, on the upper surface 261 of the second device 200-2 in the present example, the source electrode 220-2 and the drain electrode 230-2 are arranged side by side in the second direction. In other words, the first main electrode of the second device 200-2 and the second main electrode of the second device 200-2 are arranged side by side in the second direction. That is, in the same device 200, at least a part of the source electrode 220 and at least a part of the drain electrode 230 are arranged to face each other in the second direction. The entire source electrode 220 may be arranged to face the drain electrode 230 in the second direction, and as shown in FIG. 5, the entire drain electrode 230 may be arranged to face the source electrode 220 in the second direction. Also, in two devices 200 adjacent to each other in the second direction, the source electrode 220 of one device 200 and the drain electrode 230 of the other device 200 are arranged side by side in the second direction. This allows for reducing heat interference between adjacent devices 200 in the second direction.

The positive wiring 812 is connected to the drain electrode 230-1 of the first device 200-1. In the present example, the positive wiring 812 extends in the second direction, and the drain electrodes 230-1 of the plurality of first devices 200-1 are connected to each other.

The negative wiring 813 connects to the source electrode 220-2 of the second device 200-2. In the present example, the negative wiring 813 extends in the second direction, and the source electrodes 220-2 of the plurality of second devices 200-2 are connected to each other.

Inter-device wiring 814 connects the source electrode 220-1 of the first device 200-1 to the drain electrode 230-2 of the second device 200-2. In the present example, the inter-device wiring 814 extends in the second direction, and connects the source electrodes 220-1 of the plurality of first devices 200-1 to the drain electrodes 230-2 of the second devices 200-2. Note that in FIG. 5, the gate runner connected to the gate electrode 240 and the sub-source wiring connected to the sub-source electrode 250 are omitted.

The inter-device wiring 814 may be arranged between the negative wiring 813 and the positive wiring 812 in a top view. In the present example, the inter-device wiring 814 is arranged between the negative wiring 813 and the positive wiring 812 in the first direction. The inter-device wiring 814 may not overlap any of the negative wiring 813 or the positive wiring 812 in a top view. This allows the negative wiring 813, the positive wiring 812, and the inter-device wiring 814 to be arranged on the same layer, as described below, thereby reducing the thickness of the main board 810. Also, since the wiring length is shortened, the inductance can be reduced.

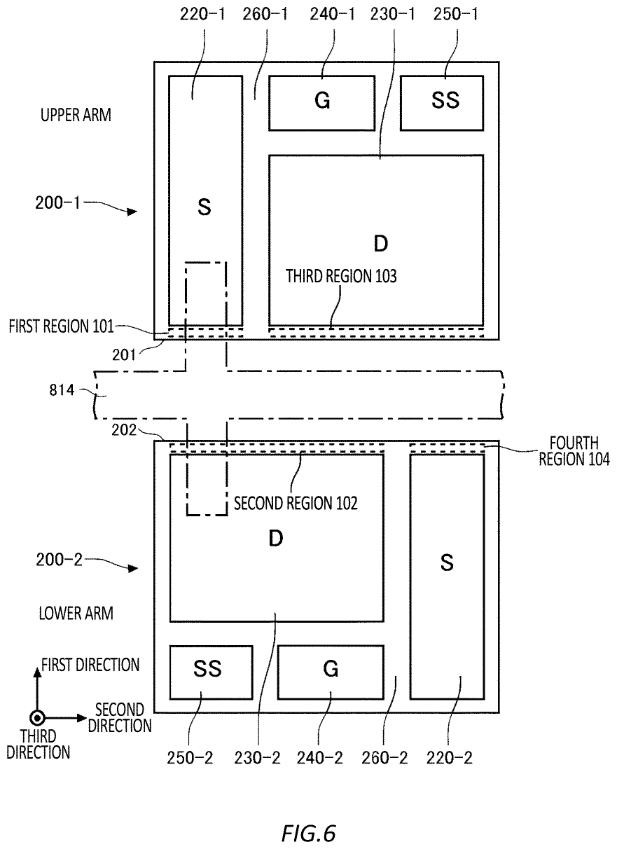

FIG. 6 illustrates an enlarged drawing of the first device 200-1 and the second device 200-2 arranged side by side in the first direction. In FIG. 6, the main board 810, the positive wiring 812 and the negative wiring 813 are omitted, and the inter-device wiring 814 is indicated by dashed lines. The first device 200-1 has a first end side 201 facing the second device. The second device 200-2 has a second end side 202 facing the first device.

On the upper surface 261 of the first device 200-1, the whole region between the source electrode 220-1 and the first end side 201 in the first direction is a region with no other electrode is provided therein. The whole region between the source electrode 220-1 and the first end side 201 is a whole region from the source electrode 220-1 to the first end side 201. In FIG. 6, the region is defined as a first region 101. The first region 101 may be a region where the portions other than the electrode of the first device 200-1 are exposed. A sealing portion 260 is provided in the first region 101 in the present example. The inter-device wiring 814 may connect a first source electrode 220-1 and a second drain electrode 230-2 via the first region 101 in a top view. This allows for prevention of interference between the positive wiring 812 or the negative wiring 813 and the inter-device wiring 814, as described below.

On the upper surface 261 of the second device 200-2, the whole region between the drain electrode 230-2 and the second end side 202 in the first direction is a region with no other electrode provided therein. The whole region between the drain electrode 230-2 and the second end side 202 is a whole region from the drain electrode 230-2 to the second end side 202. In FIG. 6, the region is defined as a second region 102. The second region 102 may be a region where portions other than the electrode of the second device 200-2 are exposed. The sealing portion 260 is provided in the second region 102 in the present example. The inter-device wiring 814 may connect the source electrode 220-1 and the drain electrode 230-2 via the first region 101 and the second region 102 in a top view. This allows for the prevention of interference between the positive wiring 812 or the negative wiring 813 and the inter-device wiring 814, as described below.

On the upper surface 261 of the first device 200-1, the whole region between the drain electrode 230-1 and the first end side 201 in the first direction may be a region with no other electrode provided therein. The whole region between the drain electrode 230-1 and the first end side 201 is a whole region from the drain electrode 230-1 to the first end side 201. In FIG. 6, the region is defined as the third region 103. The third region 103 may be a region where portions other than the electrode of the first device 200-1 are exposed. In the present example, the sealing portion 260 is provided in the third region 103. This allows for the prevention of interference between wirings even if the devices 200 of both the upper arm and the lower arm are manufactured with the same electrode arrangement. That is, when the devices 200 of the upper arm are used as the devices 200 of the lower arm, the third region 103 functions as the second region 102.

The whole region between the source electrode 220-2 and the second end side 202 in the first direction on the upper surface 261 of the second device 200-2 may be a region with no other electrode provided therein. The whole region between the source electrode 220-2 and the second end side 202 is the whole region from the source electrode 220-2 to the second end side 202. In FIG. 6, the region is defined as a fourth region 104. The fourth region 104 may be a region where portions other than the electrode of the second device 200-2 are exposed. In the present example, the sealing portion 260 is provided in the fourth region 104. This allows for the prevention of interference between wirings even if the devices 200 of both the upper arm and the lower arm are manufactured with the same electrode arrangement. That is, when the devices 200 of the lower arm are used as the devices 200 of the upper arm, the fourth region 104 functions as the first region 101.

In each device 200, a length of the source electrode 220 in the first direction may be greater than a length of the drain electrode 230 in the first direction. In the present example, the source electrode 220 is not side by side with another electrode of the same device 200 in the first direction. A length of the source electrode 220 in the second direction may be less than a length of the drain electrode 230 in the second direction. Also, in the present example, the source electrode 220 is arranged along one end side extending in the first direction of the device 200.

In the present example, the drain electrode 230 is arranged along the other end side extending in the first direction of the device 200. In the present example, a part of the drain electrode 230 is arranged side by side with the gate electrode 240 and the sub-source electrode 250 in the first direction.

In the present example, the gate electrode 240 is arranged on the side opposite to the inter-device wiring 814 in relation to the drain electrode 230. A length in the first direction of the gate electrode 240 may be shorter than those of the source electrode 220 and the drain electrode 230. A length in the second direction of the gate electrode 240 may be shorter than that of the drain electrode 230.

In the present example, the sub-source electrode 250 is arrange on the side opposite to the inter-device wiring 814 in relation to the drain electrode 230. A length in the first direction of the sub-source electrode 250 may be shorter than those of the source electrode 220 and the drain electrode 230. A length in the second direction of the sub-source electrode 250 may be shorter than that of the drain electrode 230. In the present example, the sub-source electrode 250 is arranged side by side with a part of the gate electrode 240 and the source electrode 220 in the second direction.

In the first device 200-1, a direction from the source electrode 220-1 toward the drain electrode 230-1 may be a direction opposite to a direction from the source electrode 220-2 toward the drain electrode 230-2 in the second device 200-2. In the present example, a direction from the first source electrode 220-1 toward the drain electrode 230-1 is a positive side of the second direction, and a direction from the second source electrode 220-2 toward the second drain electrode 230-2 is a negative side of the second direction.

In the present example, the arrangement of the source electrode 220-1 and the drain electrode 230-1 of the first device 200-1 matches the arrangement of 180-degree turning the arrangement of the source electrode 220-2 and the drain electrode 230-2 of the second device 200-2. Therefore, the device 200 with the same electrode arrangement as the first device 200-1 and the second device 200-2 can be used. The arrangement may also match the arrangement of the gate electrode 240 or the sub-source electrode 250. Note that the arrangements may be different. For example, the electrode arrangement of the first device 200-1 may be the electrode arrangement in the comparative example described below.

The source electrode 220-1 of the first device 200-1 and the drain electrode 230-2 of the second device 200-2 may be arranged side by side in the first direction. This allows for shortening the wiring length of the inter-device wiring 814 and lowers the inductance. Also, the drain electrode 230-1 of the first device 200-1 and the source electrode 220-2 of the second device 200-2 may be arranged side by side in the first direction.

The gate electrode 240-1 of the first device 200-1 may be arranged on the opposite side of the second device 200-2 in relation to the source electrode 220-1 or the drain electrode 230-1. In the present example, the gate electrode 240-1 is arranged on the opposite side of the second device 200-2 in relation to the drain electrode 230-1. This allows for the separation of the regions in which high-voltage wiring, such as the positive wiring 812 and low-voltage gate runner are provided. Also, since the gate driving circuit can be arranged away from high-voltage wiring or the like, the effect of noise from the high-voltage wiring can be reduced. The arrangement of the sub-source electrode 250-1 may also be similar.

Similarly, the gate electrode 240-2 of the second device 200-2 may be arranged on the opposite side of the first device 200-1 in relation to the source electrode 220-2 or the drain electrode 230-2. In the present example, the gate electrode 240-2 is arranged on the opposite side of the first device 200-1 in relation to the drain electrode 230-2. Accordingly, an effect similar to that described above can be obtained. The arrangement of the sub-source electrode 250-2 may be similar. Note that in FIG. 6, although a pair of the first device 200-1 and the second device 200-2 is described, another first device 200-1 and second device 200-2 may also be similar.

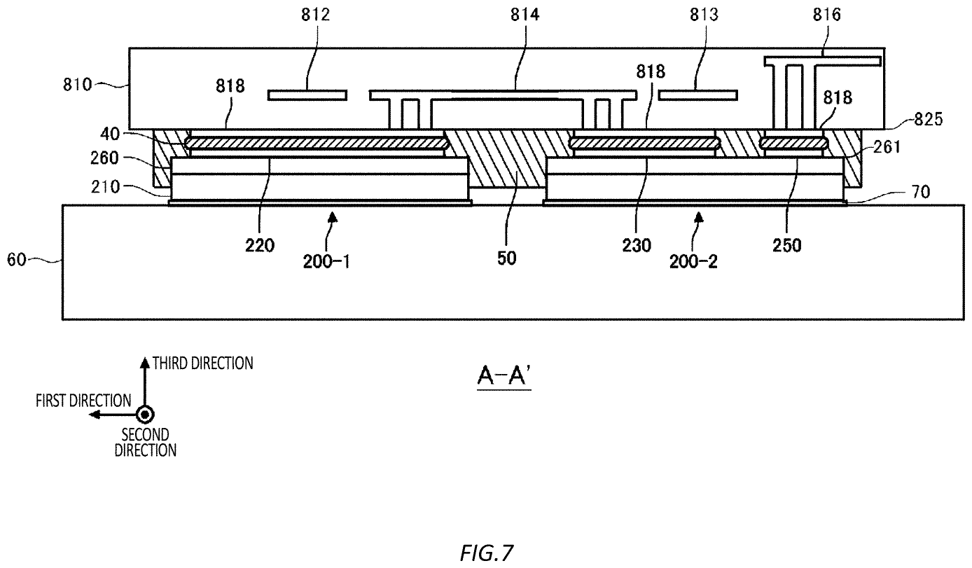

FIG. 7 illustrates an example of the A-A′ cross section in FIG. 5. The A-A′ cross section is a cross section that traverses the semiconductor circuit 800 in the first direction. In the A-A′ cross section, the semiconductor circuit 800 includes a first device 200-1, a second device 200-2, a main board 810 and a circuit sealing unit 50. Also in FIG. 7, the cooler 60 is shown. In the present specification, the module including the semiconductor circuit 800 and the cooler 60 may be referred to as a semiconductor module.

On the front surface 825, which is a surface on a side contacting the device 200 of the main board 810, a conductive connection pattern 818 may be provided. The connection pattern 818 and the inter-device wiring 814 are electrically connected via vias extending in the third direction. The connection pattern 818, the positive wiring 812 and the negative wiring 813 may also be similar in another cross-section. The positive wiring 812, the negative wiring 813 and the inter-device wiring 814 may refer to a portion extending inside a plane including the first direction and the second direction inside the main board 810. That is, the vias extending in the third direction or the connection pattern 818 provided in the front surface 825 may not be included.

The connection pattern 818 connects each electrode of the device 200 via the solder 40. In FIG. 7, the solder 40 is shown with fine hatching. In the present example, in the connection pattern 818 connected to the inter-device wiring 814, the connection pattern 818 on the positive side of the first direction is connected to the source electrode 220 of the first device 200-1, and the connection pattern 818 on the negative side of the first direction is connected to the drain electrode 230 of the second device 200-2.

As shown in FIG. 6, in the present example, the first device 200-1 has a first region 101, and the second device 200-2 has a second region 102. In this manner, the inter-device wiring 814 does not interfere with the negative wiring 813 and the positive wiring 812. Therefore, the inter-device wiring 814 is arranged at the same position (layer) as the negative wiring 813 and the positive wiring 812 in the third direction. Accordingly, the thickness of the main board 810 can be thinner. Also, there is no interference between the wiring; the wiring length can be shortened, thereby reducing the inductance can be reduced.

In the A-A′ cross-section, the main board 810 has a sub-source wiring 816. The sub-source wiring 816 is provided on a layer different from the inter-device wiring 814 or the like. One end of the sub-source wiring 816 is connected to the sub-source electrode 250 of the second device 200-2 via the vias and the connection pattern 818. The other end of the sub-source wiring 816 may be connected to the gate driving circuit.

The circuit sealing unit 50 seals at least a part of the semiconductor circuit, including the first device 200-1 and the second device 200-2. In the present example, the circuit sealing unit 50 fills between a part between the first device 200-1 and the second device 200-2 and the electrodes of each device 200. That is, the circuit sealing unit 50 and the sealing portion 260 that are insulating materials fill between the source electrode 220, the drain electrode 230 and the gate electrode 240. The insulation strength of the circuit sealing unit 50 and the sealing portion 260 may be greater than the insulation strength of air. By filling between the electrodes, the insulation performance between the electrodes can be improved.

The semiconductor circuit, including the first device 200-1 and the second device 200-2 is placed in the cooler 60. The cooler 60 may be, for example, a heat spreader, a heat sink, or a heat exchanger for liquid cooling. Each device 200 and cooler 60 may be bonded by the sinter material 70.

At least a part of the surface with the semiconductor circuit of the cooler 60 placed thereon may not be sealed. In other words, a gap between the cooler 60 and the circuit sealing unit 50 may be formed, and the circuit sealing unit 50 may not seal the surface bonded to the cooler 60 of the mounting substrate 210. This allows to prevent the circuit sealing unit 50 from becoming a thermal resistance when the heat of the device 200 is dissipated to the cooler 60. Such a circuit sealing unit 50 can be formed by bonding the device 200 and the main board 810 by using, for example, an epoxy flux type solder paste.

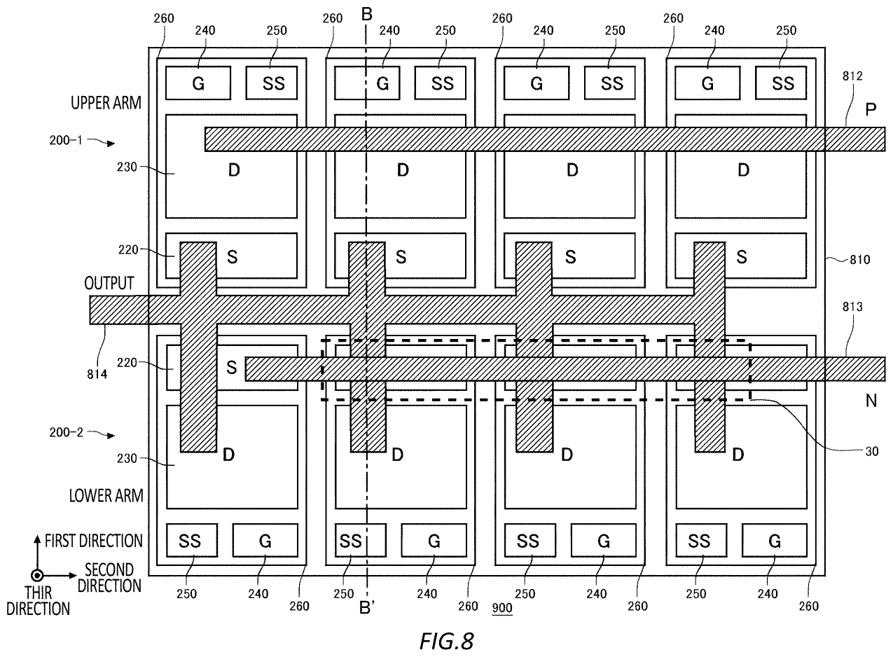

FIG. 8 illustrates the arrangement of the wiring of the semiconductor circuit 900 in the comparative example. In the present example, the semiconductor circuit 900 is different from FIG. 5 in the arrangement of the source electrode 220 of the device 200. Therefore, the arrangements of the negative wiring 813 and the inter-device wiring 814 are different.

In the present example, in the second device 200-2, the source electrode 220 is provided between the drain electrode 230 and the first device 200-1 in the first direction. Therefore, the second region 102 shown in FIG. 6 is not present. As a result, the inter-device wiring 814 and the negative wiring 813 interfere with each other in the interference region 30.

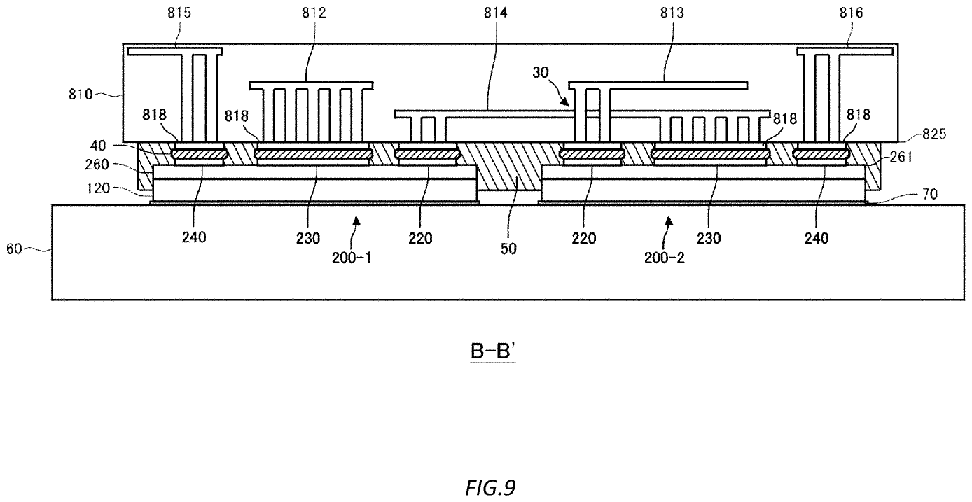

FIG. 9 illustrates an example of the B-B′ cross section in FIG. 8. The B-B′ cross section is a cross section that traverses the interference region 30 of the semiconductor circuit 900 in the first direction in the comparative example. In the comparative example, the main board 810 of the semiconductor circuit 900 has a positive wiring 812, a negative wiring 813, an inter-device wiring 814, a gate runner 815 and a sub-source wiring 816 in the B-B′ cross-section.

As described above, in the comparative example, the negative wiring 813 and the inter-device wiring 814 interfere with each other in the interference region 30. Therefore, the negative wiring 813 and the inter-device wiring 814 are provided in different layers. As a result, the thickness of the main board 810 will increase.

Note that in the present example, the gate runner 815 is provided in the same layer as the sub-source wiring 816. One end of the gate runner 815 is connected to the gate electrode 240 of the first device 200-1 via the vias and the connection pattern 818. The other end of the gate runner 815 may be connected to the gate driver IC. The arrangement of the gate runner 815 may be similar to the semiconductor circuit 800 in the example.

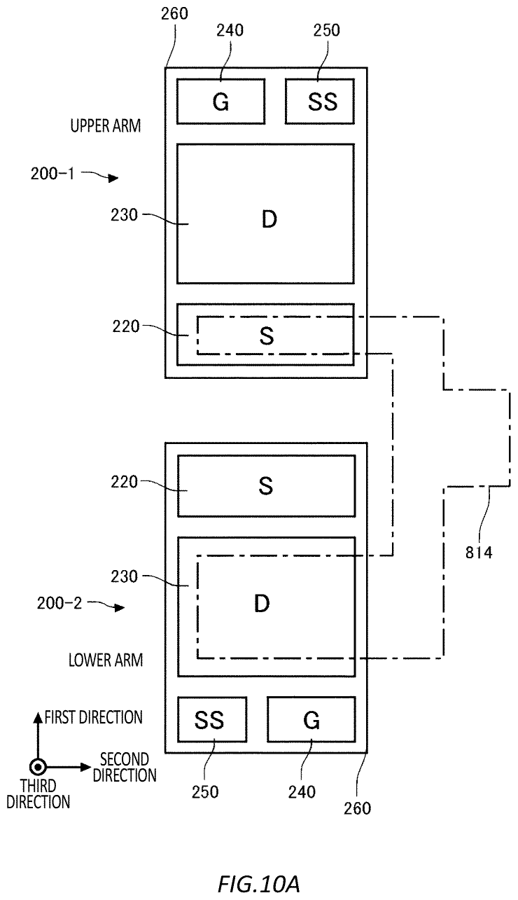

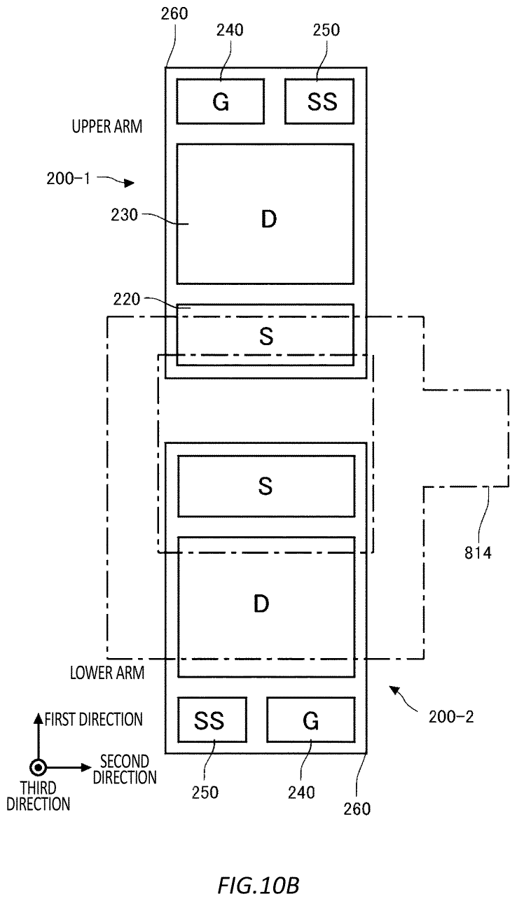

FIG. 10A illustrates an example of an enlarged drawing of the interference region 30 in a top view. In FIG. 10A, a part of one first device 200-1, one second device 200-2 and the inter-device wiring 814 are shown. In FIG. 10A, in the inter-device wiring 814, the portion connected to the source electrode 220 of the first device 200-1 and the portion connected to the drain electrode 230 of the second device 200-2 are connected at a position not overlapping the source electrode 220 of the second device 200-2 in a top view. The vias connected to the negative wiring 813 are provided from the source electrode 220 toward the above (the positive side of the third direction) of the second device 200-2.

FIG. 10B illustrates another example of the enlarged drawing of the interference region 30 in a top view. In the present example, the inter-device wiring 814 has an aperture provided to expose the source electrode 220 of the second device 200-2 in a top view. A via is provided to connect to the negative wiring 813 via the aperture from the source electrode 220 of the second device 200-2 toward the above.

In any case, the inter-device wiring 814 is detoured in the second direction, thereby the wiring length becomes longer. Therefore, the inductance due to the wiring increases more than in the example.

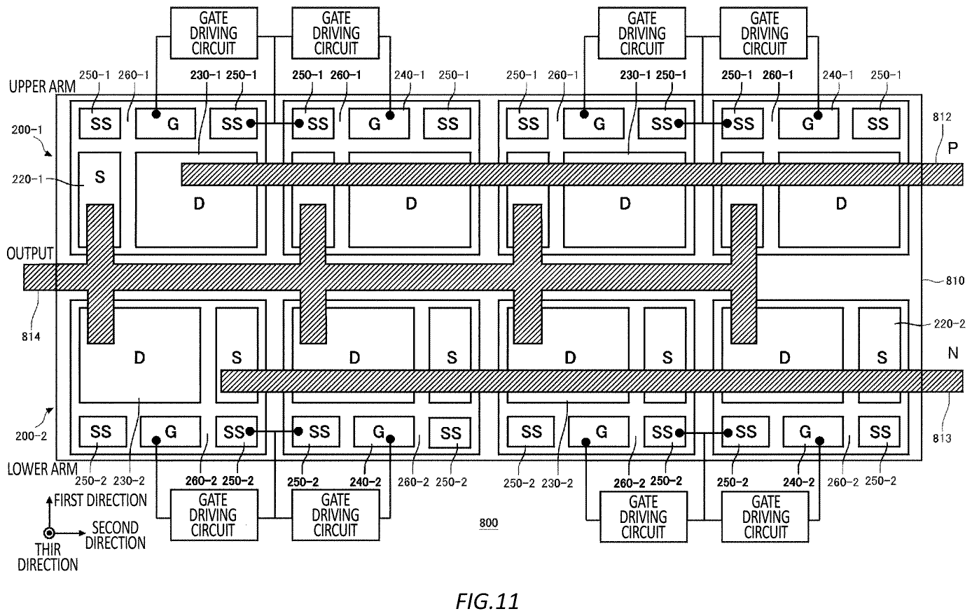

FIG. 11 illustrates a variant of the semiconductor circuit 800. In the present example, in the semiconductor circuit 800, the first device 200-1 has two sub-source electrodes 250. In each sub-source electrode 250, a part of the flowing current may flow between the drain electrode 230 and the source electrode 220.

A gate electrode 240 may be arranged between two sub-source electrodes 250. In the present example, the gate electrode 240 is arranged between two sub-source electrodes 250 in the second direction. Also, in the present example, the two first devices 200-1 are arranged side by side in the second direction. Therefore, the sub-source electrodes 250 of the two first devices 200-1 can be connected together.

In FIG. 11, the gate driving circuit is illustrated. When the gate driving circuit has a gate voltage applied between the gate electrode 240 and the sub-source electrode 250, by connecting the sub-source electrodes 250 together, the wiring of the sub-source electrodes 250 can be shared. This allows to make the wiring of the gate driving circuit to be simple.

Also, with such an arrangement, since it is possible to select which sub-source electrode 250 to use, the degree of freedom in circuit design is improved. For example, the sub-source electrodes 250 of the second and third first devices 200-1 from the end in the second direction in the drawing may be shared. The arrangement of the second device 200-2 may also be similar.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

The present specification and the drawings also disclose inventions according to the following items.

### Item 1

A semiconductor circuit, comprising:
a main board;
a plurality of first devices provided on a front surface of the main board; and
a plurality of second devices provided on the front surface of the main board,
wherein each of the first device and the second device has a plurality of electrodes including a first main electrode and a second main electrode arranged on an upper surface, and the first main electrode and the second main electrode are connected to the front surface of the main board;
the first device and the second device are arranged side by side in a first direction parallel to the front surface of the main board;
the plurality of first devices are arranged side by side in a second direction parallel to the front surface of the main board and intersecting with the first direction;
the plurality of second devices are arranged side by side in the second direction;
each of the first devices has a first end side facing the second device;
each of the second devices has a second end side facing the first device;
on the upper surface of the first device, a whole region between the first main electrode and the first end side in the first direction is a first region where no other electrode is provided; and
on the upper surface of the second device, a whole region between the second main electrode and the second end side in the first direction is a second region where no other electrode is provided.

### Item 2

The semiconductor circuit according to item 1, wherein the second main electrode of the first device and the first main electrode of the second device are arranged side by side in the first direction.

### Item 3

The semiconductor circuit according to item 1 or 2, wherein:
the first device has a gate electrode to which a control signal of the first device is input; and
the gate electrode is arranged on a side opposite to the second device with respect to the first main electrode or the second main electrode of the first device.

### Item 4

The semiconductor circuit according to item 3, wherein:
The second device has a gate electrode to which a control signal of the second device is input; and
the gate electrode of the second device is arranged on a side opposite to the first device with respect to the first main electrode or the second main electrode of the second device.

What is claimed is:

1. A semiconductor circuit, comprising:
a main board;
a plurality of first devices provided on a front surface of the main board; and
a plurality of second devices provided on the front surface of the main board,
wherein each of the first device and the second device has a plurality of electrodes including a first main electrode and a second main electrode arranged on an upper surface, and the first main electrode and the second main electrode are connected to the front surface of the main board;
the first device and the second device are arranged side by side in a first direction parallel to the front surface of the main board;
the plurality of first devices are arranged side by side in a second direction parallel to the front surface of the main board and intersecting with the first direction;
the plurality of second devices are arranged side by side in the second direction;
each of the first devices has a first end side facing the second device;
each of the second devices has a second end side facing the first device;
on the upper surface of the first device, a whole region between the first main electrode and the first end side in the first direction is a first region where no other electrode is provided; and
on the upper surface of the second device, a whole region between the second main electrode and the second end side in the first direction is a second region where no other electrode is provided.

2. The semiconductor circuit according to claim 1, wherein:
on the upper surface of the first device, a whole region between the second main electrode and the first end side in the first direction is a region where no other electrode is provided; and
on the upper surface of the second device, a whole region between the first main electrode and the second end side in the first direction is a region where no other electrode is provided.

3. The semiconductor circuit according to claim 1, wherein the first main electrode and the second main electrode are arranged side by side in the second direction on the upper surface of the first device.

4. The semiconductor circuit according to claim 1, wherein:
the first device has:
a semiconductor chip that is a switching element; and
a gate electrode arranged on the upper surface,
the semiconductor chip includes:
a first main pad and a gate pad arranged on an upper surface of the semiconductor chip; and
a second main pad arranged on a lower surface of the semiconductor chip,
the first main electrode is connected to the first main pad, the second main electrode is connected to the second main pad, and the gate electrode is connected to the gate pad; and
an insulating material is filled between the first main electrode, the second main electrode and the gate electrode.

5. The semiconductor circuit according to claim 1, wherein a direction from the first main electrode toward the second main electrode in the first device is a direction opposite to a direction from the first main electrode toward the second main electrode in the second device.

6. The semiconductor circuit according to claim 1, wherein the first main electrode of the first device and the second main electrode of the second device are arranged side by side in the first direction.

7. The semiconductor circuit according to claim 1, further comprising an inter-device wiring which connects the first main electrode of the first device and the second main electrode of the second device.

8. The semiconductor circuit according to claim 7, comprising:
a positive wiring by which the second main electrodes of the plurality of first devices are connected to each other; and
a negative wiring by which the first main electrodes of the plurality of second devices are connected to each other,
wherein the inter-device wiring connects the first main electrodes of the plurality of first devices and the second main electrodes of the plurality of second devices via each of the first region and the second region.

9. The semiconductor circuit according to claim 8, wherein the inter-device wiring is arranged between the positive wiring and the negative wiring in a top view.

10. The semiconductor circuit according to claim 9, wherein the inter-device wiring does not overlap any of the positive wiring and the negative wiring in a top view.

11. The semiconductor circuit according to claim 10, wherein the inter-device wiring is arranged at a position identical to the positive wiring and the negative wiring in a third direction perpendicular to the front surface of the main board.

12. The semiconductor circuit according to claim 8, wherein the main board is a printed circuit board, on which the positive wiring, the negative wiring and the inter-device wiring are provided.

13. The semiconductor circuit according to claim 1, wherein an arrangement of the first main electrode and the second main electrode of the first device matches an arrangement obtained by 180-degree turning an arrangement of the first main electrode and the second main electrode of a second device.

14. The semiconductor circuit according to claim 1, wherein:
the first device has:
a first semiconductor chip that is a switching element; and
a gate electrode to which a control signal of the first semiconductor chip is input, and
the gate electrode is arranged at a position not overlapping the first semiconductor chip.

15. The semiconductor circuit according to claim 1, wherein:
the first device has:
a first semiconductor chip that is a switching element; and
a sub-electrode through which a current flows, corresponding to a current flowing between the second main electrode and the first main electrode, and
the sub-electrode is arranged at a position not overlapping the first semiconductor chip.

16. The semiconductor circuit according to claim 1, wherein:
the first device has a first semiconductor chip that is a switching element; and
the first main electrode is arranged at a position not overlapping the first semiconductor chip.

17. The semiconductor circuit according to claim 1, wherein:
the first device has:
a gate electrode to which a control signal of the first device is input; and
two sub-electrodes through which a current flows, which corresponds to a current flowing between the second main electrode and the first main electrode, and
the gate electrode is arranged between the two sub-electrodes.

18. The semiconductor circuit according to claim 17, wherein:
two of the first devices are arranged side by side in the second direction; and
the sub-electrodes of the two first devices are connected to each other.

19. A semiconductor module, comprising:
a semiconductor circuit according to claim 1;
a cooler in which the semiconductor circuit is placed; and
a circuit sealing unit which seals at least a part of the semiconductor circuit.

20. The semiconductor module according to claim 19, wherein at least a part of a surface is not sealed, on which the semiconductor circuit of the cooler is placed.
